(19) United States
(12) Patent Application Publication
(10) Pub. No.: US 2018/0308696 A1
(43) Pub. Date: Oct. 25, 2018

(54) LOW CONTACT RESISTANCE GRAPHENE DEVICE INTEGRATION

(71) Applicant: Texas Instruments Incorporated, Dallas, TX (US)

(72) Inventors: Luigi Colombo, Dallas, TX (US); Archana Venugopal, Dallas, TX (US)

(73) Assignee: Texas Instruments Incorporated, Dallas, TX (US)

(21) Appl. No.: 15/496,814

(22) Filed: Apr. 25, 2017

(51) Int. Cl. H01L 21/04; H01L 29/16; H01L 29/786; H01L 29/45

(52) U.S. Cl. CPC H01L 21/043; H01L 29/1606; H01L 29/45; H01L 29/78618; H01L 29/78684

(57) ABSTRACT

An electronic device has a graphene layer having one or more atomic layers of graphene, with low resistance contacts that includes a carbon-doped metal layer directly on the graphene layer. The electronic device is formed by forming a carbon-doped metal layer on a substrate layer of the electronic device. The carbon-doped metal layer is subsequently heated to a temperature above which carbon in the carbon-doped metal layer becomes mobile, and subsequently cooled. The carbon in the carbon-doped metal forms the graphene layer under the carbon-doped metal layer and over the substrate layer. The carbon-doped metal layer is removed from an area outside of a contact area, leaving the carbon-doped metal in the contact area to provide a contact layer to the graphene layer.

### FIELD

This disclosure relates to the field of electronic devices. More particularly, this disclosure relates to graphene layers in electronic devices.

### BACKGROUND

Graphene has desirable properties for components of electronic devices, such as high electron mobility, high current carrying capacity, high thermal conductivity, and ambipolar behaviors. Successful integration of graphene requires a process that provides a relatively defect-free graphene layer and low resistance contacts to the graphene layer, at a fabrication cost that is competitive with alternate structures using conventional materials and processes. Much effort has been spent in pursuit of these goals, yet commercially viable integration of graphene in electronic devices has remained problematic.

### SUMMARY

The following presents a simplified summary in order to provide a basic understanding of one or more aspects of the disclosure. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to a more detailed description that is presented later.

A method of forming an electronic device including a graphene layer with low resistance contacts includes forming a carbon-doped metal layer on a substrate layer of the electronic device. The carbon-doped metal layer is subsequently heated to a temperature above which carbon in the carbon-doped metal layer is at a saturation concentration. The carbon-doped metal layer is subsequently cooled to form a graphene layer, which includes one or more atomic layers of graphene, at a bottom surface of the carbon-doped metal layer directly adjacent to the substrate layer. The carbon-doped metal layer is removed from an area outside of a contact area, leaving the carbon-doped metal in the contact area to provide a low resistance contact layer to the graphene layer. An electronic device including a graphene layer with a contact layer having carbon-doped metal is also disclosed.

### BRIEF DESCRIPTION OF THE VIEWS OF THE DRAWINGS

FIG. 1 is a cross section of an example electronic device having a graphene layer and contact layers of carbon-doped metal on the graphene layer.

FIGS. 2A through 2I are cross sections of an electronic device which includes a graphene layer having carbon-doped metal contact layers, depicted in successive stages of an example method of formation.

FIGS. 3A through 3G are cross sections of an electronic device including a graphene layer having carbon-doped metal contact layers, depicted in successive stages of another example method of formation.

FIGS. 4A through 4E depict another method of forming a carbon-doped metal layer for a process of forming an electronic device having a graphene layer with carbon-doped contact layers.

FIG. 5 is a cross section of another example electronic device having a graphene layer and a contact layer of carbon-doped metal on the graphene layer.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

It is noted that terms such as top, bottom, over, and under may be used in this disclosure. These terms should not be construed as limiting the position or orientation of a structure or element, but should be used to provide spatial relationship between structures or elements.

For the purposes of this disclosure, it will be understood that, if an element is referred to as being “on” or “over” another element, it may be directly on or directly over the other element, or intervening elements may be present. If an element is referred to as being “directly on” or “directly over” to another element, it is understood there are no other intentionally disposed intervening elements present.

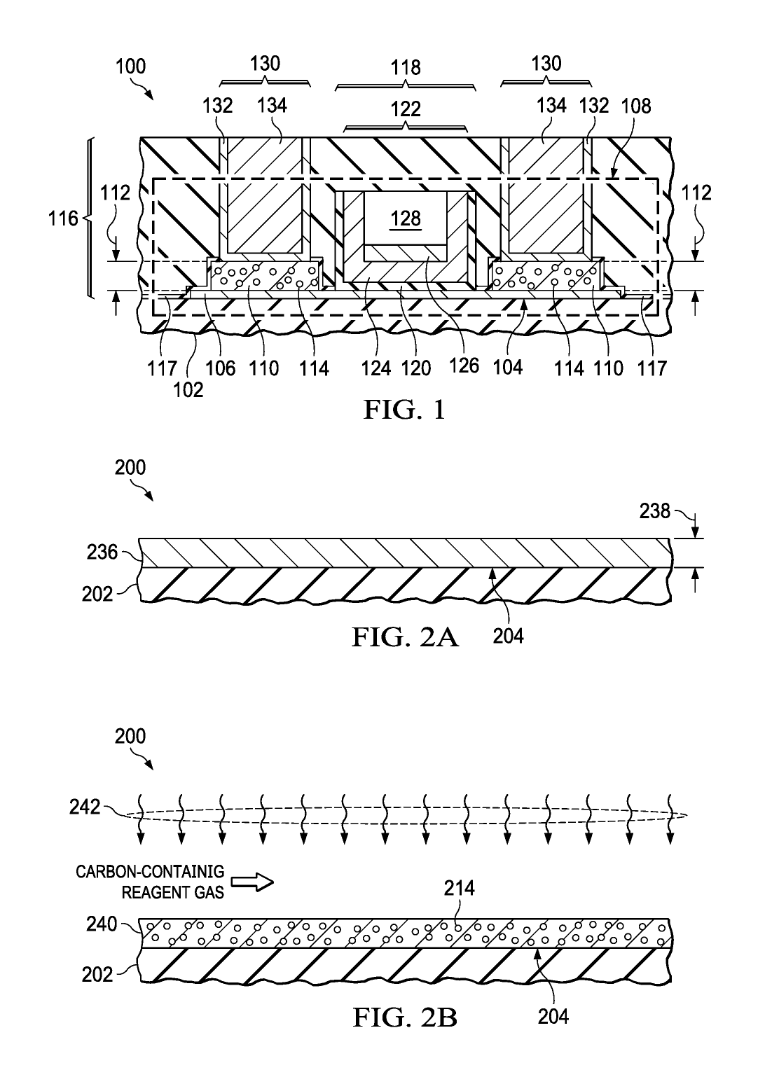

FIG. 1 is a cross section of an example electronic device having a graphene layer and contact layers of carbon-doped metal on the graphene layer. The electronic device 100 may be, for example, an integrated circuit, a discrete electronic component such as a resistor, capacitor, or antenna, an electronic display member such as a light emitting diode screen, an electronic transducer such as a speaker or actuator, or an electronic sensor. The electronic device 100 has a substrate layer 102 which may include dielectric material extending to a top surface 104 of the substrate layer 102. The dielectric material may include, for example, silicon dioxide, silicon dioxide-based material, silicon nitride, aluminum oxide, ceramic, silicone polymer, or organic polymer. The substrate layer 102 may be disposed over an electronic material such as silicon, silicon carbide, gallium arsenide, gallium nitride, cadmium telluride, perovskite, or graphene. The electronic device 100 includes a graphene layer 106 disposed over the top surface 104. The graphene layer 106, which includes one or more atomic layers of graphene, provides a conductive member of a component 108 of the electronic device 100. For the purposes of this disclosure, the term “atomic layer of graphene” is understood to refer to a layer of graphene that is one atom thick. In the instant example, the component 108 is implemented as a field effect transistor 108, and the graphene layer 106 provides a channel layer for the field effect transistor 108. Other implementations of the component 108 using the graphene layer 106, such as a resistor, capacitor, or sensor, are within the scope of the instant example. Contact layers 110 of a carbon-doped metal are disposed directly on the graphene layer 106. The contact layers 110 do not extend over the entire graphene layer 106. The contact layers 110 may include, for example, cobalt, nickel, copper, ruthenium, rhodium, palladium, silver, rhenium, iridium, platinum, gold, or any combination thereof. These metals are not an exhaustive list, and are provided by way of examples. Other metals that are suitable for incorporating carbon to form contact layers on graphene layers are within the scope of the instant example. The contact layers 110 may include a homogeneous alloy or mixture of two or more different metals, for example a nickel copper alloy. The contact layers 110 may include a layered structure of two or more layers with different metals. Carbon atoms 114 are depicted schematically in the contact layers 110 by circles in FIG. 1. A concentration of the carbon atoms 114 in the carbon-doped metal may be a few parts per million to several atomic percent, which may be approximately equal to a saturation concentration of carbon in the metal at a temperature at which the graphene layer 106 is formed. For example, cobalt, nickel, palladium, and rhenium have higher carbon saturation concentrations than silver, gold, and copper. The temperature at which the graphene layer 106 is formed may be, for example, approximately 400° C. to approximately 1100° C. At temperatures lower than approximately 400° C., the carbon atoms 114 may not have sufficient mobility to form the graphene layer 106. At temperatures above approximately 1100° C., degradation of the carbon-doped metal, such as loss of adhesion to the substrate layer 102 may occur, or degradation of materials and components of the electronic device 100 may occur. An average thickness 112 of the contact layers 110 may also depend on the saturation concentration of carbon in the metal at the temperature at which the graphene layer 106 was formed. Metals that have carbon saturation concentrations in the 1 atomic percent to 3 atomic percent range may have the average thickness 112 in the range of 50 nanometers to 500 nanometers. Metals which have lower carbon saturation concentrations may have correspondingly greater values for the average thickness 112. A contact resistivity between the contact layers 110 and the graphene layer 106 may be less than 10⁻⁷ ohm cm². In the instant example, the contact layers 110 provide source and drain terminals for the field effect transistor 108, which includes the contact layers 110 and a gate structure 118.

An upper dielectric layer 116 is disposed over the substrate layer 102 and the field effect transistor 108. The upper dielectric layer 116 may include, for example, a liner of silicon nitride, a main layer of silicon dioxide-based material such as boron phosphorus silicate glass (BPSG), and a cap layer of silicon nitride or silicon oxy-nitride. The gate structure 118 of the field effect transistor 108 is disposed in the upper dielectric layer 116 on the graphene layer 106 between the contact layers 110. The gate structure 118 includes a gate dielectric layer 120 including high-k dielectric material such as hafnium oxide, zirconium oxide, or the like. A gate 122 is disposed on the gate dielectric layer 120. The gate 122 may include a liner 124, a work function layer 126 and a fill layer 128 as depicted in FIG. 1. Alternatively, the gate 122 may have a homogeneous structure of polycrystalline silicon, metal silicide, titanium nitride, or elemental metal such as nickel, cobalt or ruthenium. Other structures for the gate 122 are within the scope of the instant example. In the instant example, vertical contacts 130 are disposed through the upper dielectric layer 116, making direct connections to the contact layers 110. For the purposes of this disclosure, the term “vertical” is understood to refer to a direction perpendicular to the plane of the instant top surface of the electronic device 100. In one implementation of the instant example, the vertical contacts 130 may include liners 132 of titanium, and titanium nitride or tantalum nitride, and fill metal 134 of tungsten. In another implementation, the vertical contacts 130 may liners 132 of tantalum or tantalum nitride and fill metal 134 of copper. In a further implementation, the vertical contacts 130 may include carbon nanotubes, graphene or graphitic material. In one version of the instant example, the vertical contacts 130 may have a same structure and composition as contacts to active components of the electronic device 100. In another version, the vertical contacts 130 may have a same structure and composition as vias to lateral interconnects of the electronic device 100. The low values for the contact resistivity between the contact layers 110 and the graphene layer 106 may provide a desired value for drive current for the field effect transistor 108.

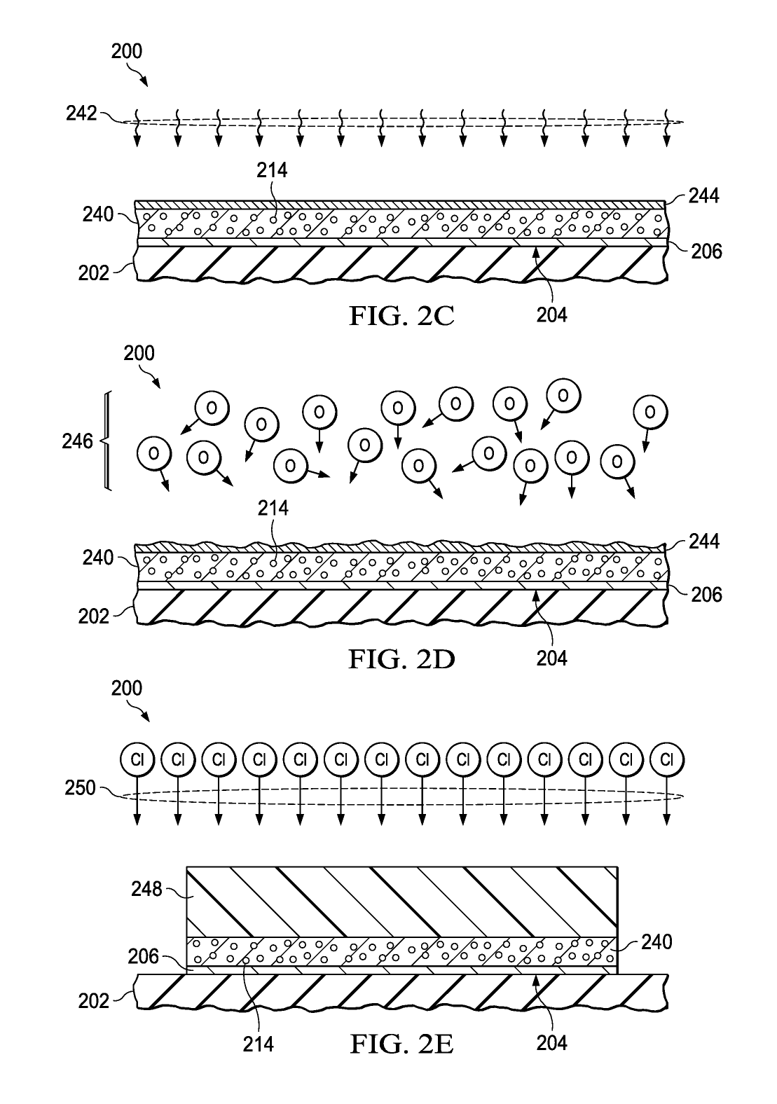

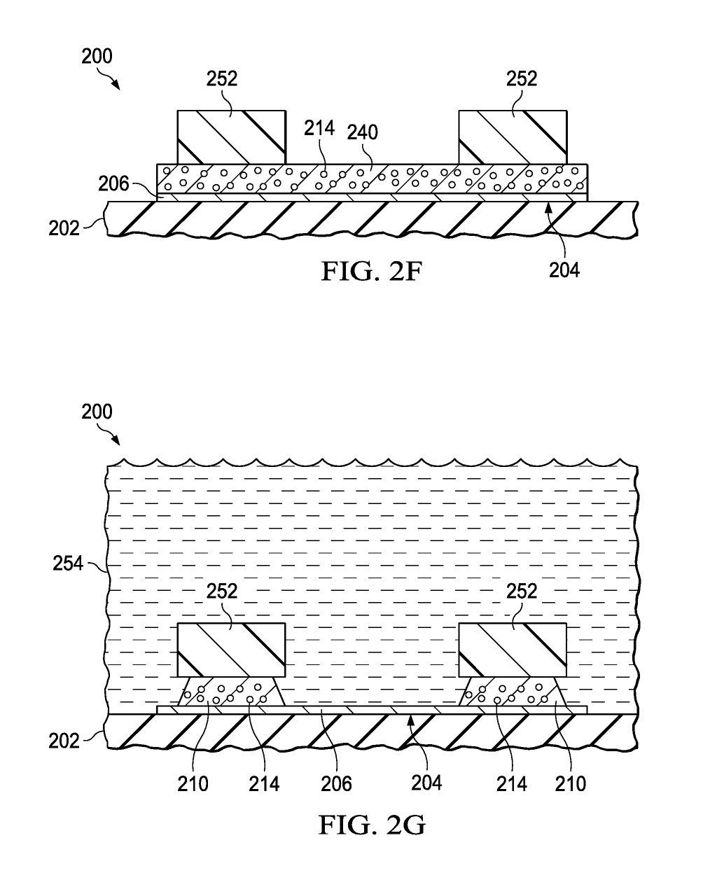

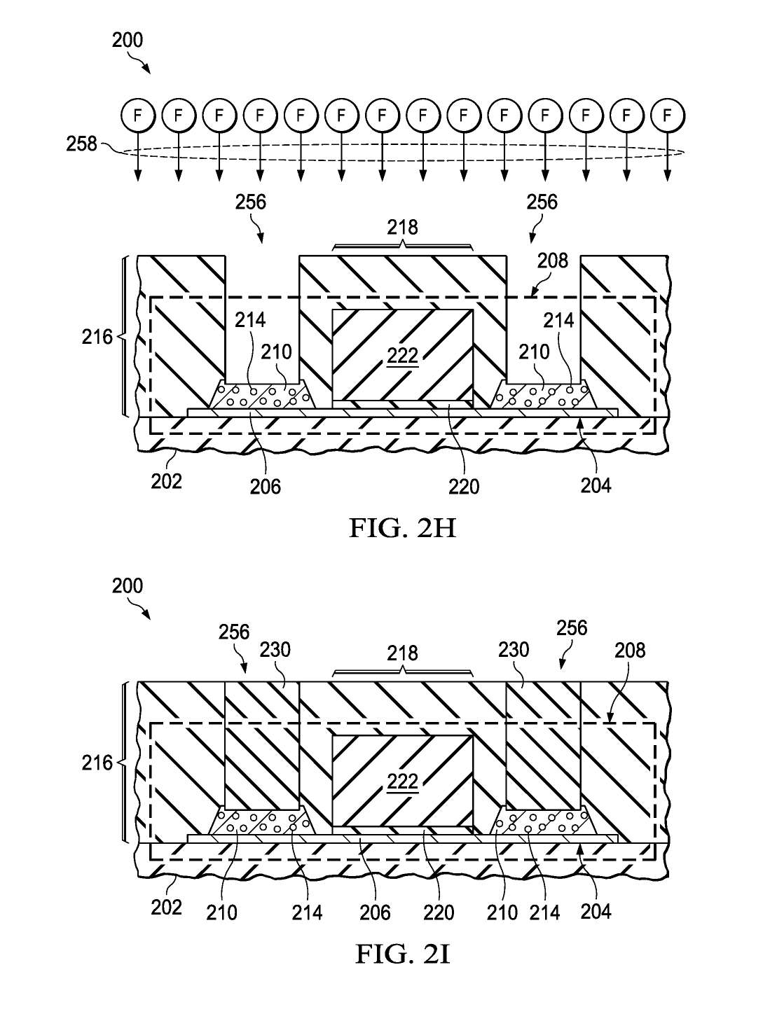

FIGS. 2A through 2I are cross sections of an electronic device which includes a graphene layer having carbon-doped metal contact layers, depicted in successive stages of an example method of formation. Referring to FIG. 2A, the electronic device 200 has a substrate layer 202. The substrate layer 202 may include a dielectric material extending to a top surface 204 of the substrate layer 202. A metal layer 236 is formed over the top surface 204. In the instant example, the metal layer 236 may be substantially free of carbon, that is a concentration of carbon in the metal layer 236 immediately after being formed may be less than a few parts per million. The metal layer 236 includes a metal suitable for subsequent formation of graphene, for example cobalt, nickel, copper, ruthenium, rhodium, palladium, silver, rhenium, iridium, platinum, gold, or any combination thereof. As explained in reference to FIG. 1, these metals are not an exhaustive list, and are provided by way of examples. Other metals, now known or hereafter identified, are within the scope of the instant example. The metal layer 236 may include a homogeneous alloy or mixture of two or more different metals. The metal layer 236 may include a layered structure of two or more layers with different metals, for example a copper/nickel/copper stack. The metal layer 236 may be formed, for example, by a sputter process, an evaporation process, a chemical vapor deposition (CVD) process, or an atomic layer deposition (ALD) process. A thickness 238 of the metal layer 236 is affected by a saturation concentration of carbon in the metal layer 236 at a temperature at which a graphene layer is subsequently formed. In the instant example, carbon will be introduced into the metal layer 236 at an elevated temperature. Sufficient carbon must be introduced into the metal layer 236 to provide carbon atoms for the subsequently-formed graphene layer 206 of FIG. 2C. For instances of the metal layer 236 which include primarily metals having high saturation concentrations of carbon, such as cobalt, nickel, rhenium, and/or palladium, the thickness 238 may be, for example, 50 nanometers to 500 nanometers. For instances of the metal layer 236 which include primarily metals having lower saturation concentrations of carbon, such as silver, copper, gold, or platinum, the thickness 238 may be greater than 500 nanometers.

Referring to FIG. 2B, carbon atoms 214, denoted schematically by circles in FIG. 2B, are introduced into the metal layer 236 of FIG. 2A to form a carbon-doped metal layer 240 over the top surface 204 of the substrate layer 202. In the instant example, the carbon atoms 214 may be introduced into the metal layer 236 by heating the metal layer 236 while flowing a carbon-containing reagent gas, denoted as “CARBON-CONTAINING REAGENT GAS” in FIG. 2A, over the metal layer 236. The metal layer 236 may be heated to a temperature of, for example, approximately 400° C. to approximately 1100° C. The metal layer 236 is heated by a heating process 242. In some versions of the instant example, the electronic device 200 may be disposed in a wafer furnace or other equipment capable of batch operation, providing low process cost. In other versions of the instant example, the electronic device 200 may be disposed in a chemical vapor deposition (CVD) chamber with a heated substrate chuck, providing a high level of process control. In further versions of the instant example, the electronic device 200 may be disposed in a rapid thermal processor (RTP) chamber with a radiant heat source, providing high throughput. The carbon-containing reagent gas may include methane, ethane, propane or other alkane, ethanol, propanol or other alcohol, or an aromatic reagent such as camphor. Other carbon-containing reagent gases are within the scope of the instant example. The heating process 242 is continued and the carbon-containing reagent gas is flowed over the metal layer 236 until a desired concentration of the carbon atoms 214 is attained in the carbon-doped metal layer 240 at a desired temperature. A temperature of at least approximately 400° C. provide adequate mobility of the carbon atoms 214 in the metal layer 236. The desired concentration of the carbon atoms 214 may be close to a carbon saturation concentration at the desired temperature of the carbon-doped metal layer 240 while the carbon atoms 214 are being introduced. The carbon saturation concentration depends on the metal composition of the metal layer 236 and on the temperature of the carbon-doped metal layer 240. Generally, the carbon saturation concentration increases as the temperature of the carbon-doped metal layer 240 increases. Process control of the concentration of the carbon atoms 214 is facilitated by increasing the temperature of the carbon-doped metal layer 240. However, the temperature is limited by the necessity of avoiding degradation to existing components and materials of the electronic device 100. In versions of the instant example in which the existing components and materials are free of plastics, transistors, metal interconnects and the like, the temperature may extend to approximately 1100° C. The presence of temperature sensitive materials or components may necessitate a reduced temperature. After the desired concentration of the carbon atoms 214 is attained, flow of the carbon-containing reagent gas ceases.

Referring to FIG. 2C, the carbon-doped metal layer 240 is cooled by reducing the thermal power provided by the heating process 242. The carbon-doped metal layer 240 may be cooled by turning off the thermal power abruptly or by decreasing the thermal power, as indicated schematically in FIG. 2C, at a cooling rate of, for example, 1° C./minute to 150° C./second. Lower cooling rates in a range of 1° C./minute to 10° C./minute may be applicable for versions of the instant example performed in furnace equipment capable of batch operation. Medium cooling rates in a range of 10° C./minute to 1° C./second may be applicable of versions of the instant example performed in a CVD chamber with a heated substrate chuck. Higher cooling rates in a range of 1° C./second to 150° C./second may be applicable of versions of the instant example performed in a RTP chamber with a radiant heat source. As the carbon-doped metal layer 240 cools, the carbon saturation concentration of the carbon-doped metal layer 240 drops below the actual carbon concentration of the carbon-doped metal layer 240 while the carbon atoms 214 are still mobile at the instant temperature of the carbon-doped metal layer 240. A first portion of the carbon atoms 214 migrates to a lower surface of the carbon-doped metal layer 240 adjacent to the top surface 204 of the substrate layer 202 and forms a graphene layer 206 over the top surface 204 and under the carbon-doped metal layer 240. A second portion of the carbon atoms 214 migrates to an upper surface of the carbon-doped metal layer 240 and forms a discardable graphitic layer 244 located opposite from the graphene layer 206. The discardable graphitic layer 244 may include graphene or other graphitic material, and may include other forms of carbon.

Referring to FIG. 2D, in the instant example, the discardable graphitic layer 244 may optionally be removed, leaving at least a portion of the carbon-doped metal layer 240 intact on the graphene layer 206. The discardable graphitic layer 244 may be removed, for example, by an ash process 246 using oxygen radicals, as depicted schematically in FIG. 2D. Other processes for removing the discardable graphitic layer 244 such as dry etch processes using ozone, are within the scope of the instant example. After the discardable graphitic layer 244 is removed, a top surface of the carbon-doped metal layer 240 is substantially free of graphitic material, that is an amount of graphitic material on the top surface of the carbon-doped metal layer 240 is sufficiently low so as not to interfere with forming electrical connections to subsequently-formed contact layers of the carbon-doped metal layer 240.

Referring to FIG. 2E, a graphene etch mask 248 is formed over the carbon-doped metal layer 240, covering an area for a subsequently-formed component using the graphene layer 206. The graphene etch mask 248 may include, for example, photoresist formed by a photolithographic process, and may also include anti-reflection layers such as a bottom anti-reflection coat (BARC). The graphene etch mask 248 may include, in another example, hard mask materials such as silicon nitride. The carbon-doped metal layer 240 and the graphene layer 206 are removed where exposed by the graphene etch mask 248. The carbon-doped metal layer 240 and the graphene layer 206 may be removed by a dry etch process 250 which may include a reactive ion etch (ME) process using halogen radicals, depicted schematically in FIG. 2E as chlorine (Cl) radicals. The carbon-doped metal layer 240 and the graphene layer 206 may be removed by a wet etch process. The graphene etch mask 248 is subsequently removed, for example by an ash process. The carbon-doped metal layer 240 remains in place over the graphene layer 206 after the graphene etch mask 248 is removed.

Referring to FIG. 2F, a contact etch mask 252 is formed over the carbon-doped metal layer 240, covering areas for subsequently-formed contact layers of the carbon-doped metal layer 240. The contact etch mask 252 may include photoresist formed by a photolithographic process. The photoresist may undergo a bake process to improve adhesion to the carbon-doped metal layer 240 to reduce undercut in a subsequent wet etch process.

Referring to FIG. 2G, the carbon-doped metal layer 240 of FIG. 2F is removed where exposed by the contact etch mask 252, leaving the remaining carbon-doped metal layer 240 under the contact etch mask 252 to provide contact layers 210 on the graphene layer 206. The process of removing the carbon-doped metal layer 240 is performed so as to leave the graphene layer 206 substantially intact, that is, the remaining graphene layer 206 provides functionality for the subsequently-formed component having the graphene layer 206. The carbon-doped metal layer 240 may be removed using a wet etch process 254, as indicated in FIG. 2G. The wet etch process 254 may include, for example, nitric acid in an organic solvent, an aqueous solution including nitric acid, an aqueous solution of ferric chloride (FeCl₃), an aqueous solution of potassium permanganate (KMnO4), or a dilute aqueous solution of hydrofluoric acid. The wet etch process 254 may include a timed etch using an aqueous nitric acid solution or an aqueous potassium permanganate solution, which removes a portion of the carbon-doped metal layer 240, followed by a dilute aqueous solution of hydrofluoric acid to remove the remaining carbon-doped metal layer 240 while reducing oxidation of the underlying graphene layer 206. After the carbon-doped metal layer 240 is removed where exposed by the contact etch mask 252, the contact etch mask 252 is removed, for example by a solvent-based wet process to avoid oxidation of the graphene layer 206.

Referring to FIG. 2H, a gate structure 218 of a component 208, represented in FIG. 2H as a field effect transistor 208, is formed over the graphene layer 206. The gate structure 218 of the instant example may include a gate dielectric layer 220 over the graphene layer 206 and a gate 222 over the gate dielectric layer 220. Other implementations of the gate structure 218 are within the scope of the instant example. An upper dielectric layer 216 is formed over the substrate layer 202, the graphene layer 206, the gate structure 218, and the contact layers 210. The upper dielectric layer 216 may include one or more layers of dielectric material, for example as disclosed in reference to FIG. 1. The upper dielectric layer 216 is sometimes referred to as the pre-metal dielectric (PMD) layer 216. Contact holes 256 are formed through the upper dielectric layer 216, exposing the contact layers 210. The contact holes 256 may be formed, for example, by an RIE process 258 using fluorine radicals, as indicated schematically in FIG. 2H. The process used to form the contact holes 256 may remove a portion of the contact layers 210, as depicted in FIG. 2H. The contact layers 210 advantageously protect the underlying graphene layer 206 from degradation by the process used to form the contact holes 256.

Referring to FIG. 21, vertical contacts 230 are formed in the contact holes 256 to make electrical connections to the contact layers 210. The contact layers provide low resistance electrical connections between the vertical contacts 230 and the graphene layer 206. The vertical contacts 230 may have a liner and fill metal structure, similar to the vertical contacts 130 of FIG. 1. Other structures of the vertical contacts 230, for example solid fill metal structures, are within the scope of the instant example.

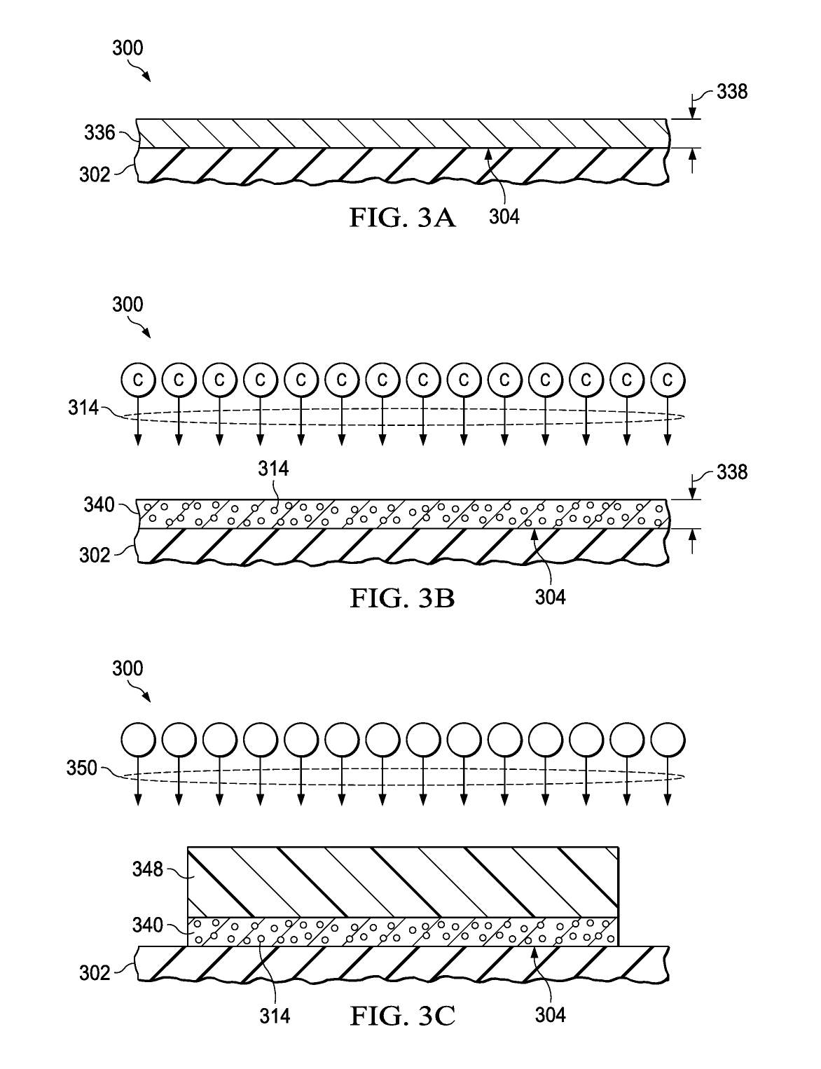

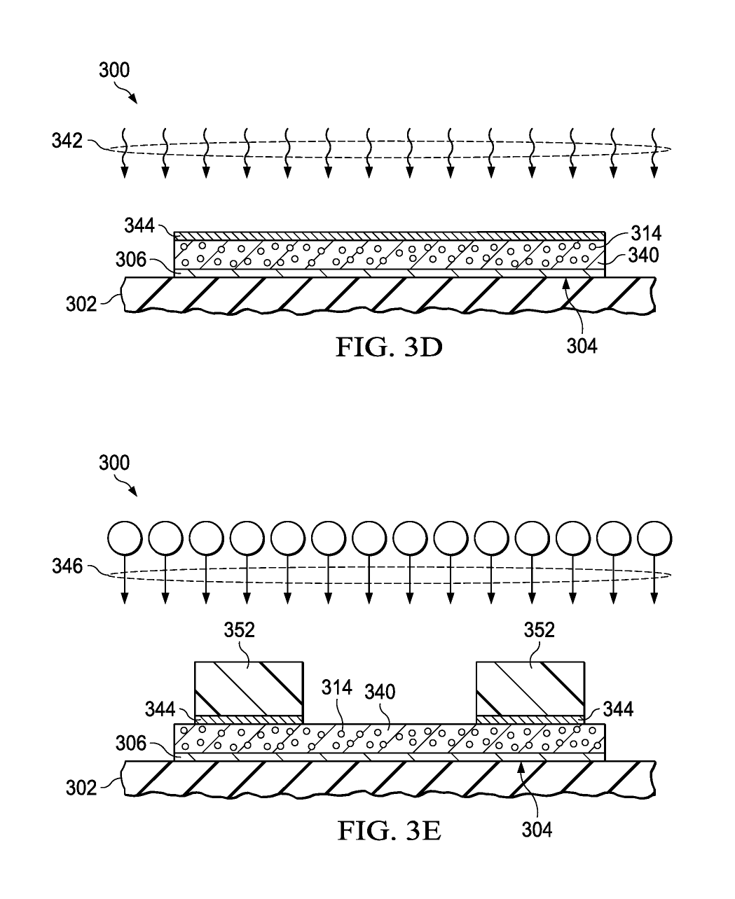

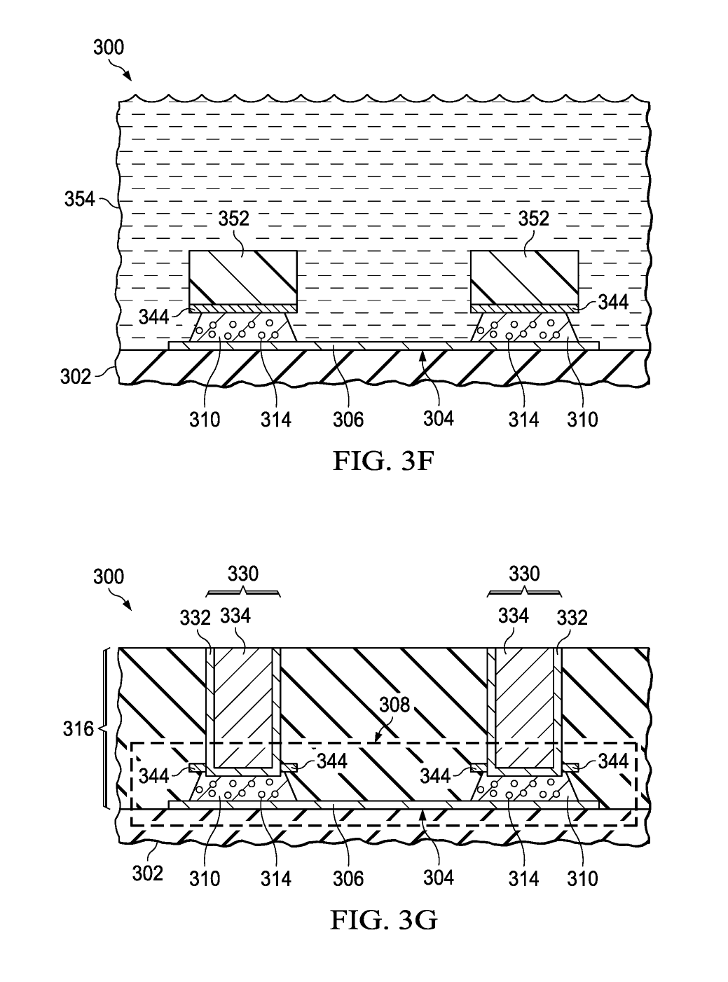

FIGS. 3A through 3G are cross sections of an electronic device including a graphene layer having carbon-doped metal contact layers, depicted in successive stages of another example method of formation. Referring to FIG. 3A, the electronic device 300 has a substrate layer 302 with a top surface 304. A metal layer 336, which may be substantially free of carbon, is formed over the top surface 304. The metal layer 336 includes a metal suitable for subsequent formation of graphene, for example cobalt, nickel, copper, ruthenium, rhodium, palladium, silver, rhenium, iridium, platinum, gold, or any combination thereof. The metal layer 336 may be formed, for example, by the processes disclosed in reference to FIG. 2A. A thickness 338 of the metal layer 336 may be, for example, 150 nanometers to 250 nanometers.

Referring to FIG. 3B, carbon atoms 314 are implanted into the metal layer 336 of FIG. 3A to form a carbon-doped metal layer 340. In the instant example, carbon is introduced into the metal layer 336 at relatively low temperature under conditions far from thermal equilibrium, allowing a desired carbon content to be attained. The subsequently-formed graphene layer will be formed under conditions approximating thermal equilibrium. Hence, sufficient carbon must be introduced to provide carbon for the subsequently-formed graphene layer as well as a subsequently-formed discardable graphitic layer. A single atomic layer of graphene has a carbon atom density of approximately 4×10¹⁵ cm⁻². Hence, a dose of the implanted carbon atoms 314 may be as low as 1×10¹⁶ cm⁻² to form the graphene layer with one atomic layer of graphene. Alternatively, the dose of the implanted carbon atoms 314 may exceed 6×10¹⁶ cm⁻² to form the graphene layer with five atomic layer of graphene. Moreover, the dose of the implanted carbon atoms 314 is sufficient to provide carbon for the carbon atoms 314 remaining in the carbon-doped metal layer 340 after formation of the graphene layer.

Referring to FIG. 3C, a graphene etch mask 348 is formed over the carbon-doped metal layer 340, covering an area for the subsequently-formed graphene layer. The graphene etch mask 348 may include, for example, photoresist and anti-reflection layers, or may include hard mask materials. The carbon-doped metal layer 340 is removed where exposed by the graphene etch mask 348, for example, by a dry etch process 350. Alternatively, the carbon-doped metal layer 340 may be removed by a wet etch process. The graphene etch mask 348 is subsequently removed, for example by an ash process. The carbon-doped metal layer 340 remains in place after the graphene etch mask 348 is removed.

Referring to FIG. 3D, the carbon-doped metal layer 340 is heated by a heating process 342 to a temperature of, for example, approximately 400° C. to approximately 1100° C. The heating process 342 which may be a radiant heat process 342 as depicted schematically in FIG. 2B. Alternately, the heating process 342 may be a wafer furnace batch process or a single substrate heated chuck process. As a temperature of the carbon-doped metal layer 340 rises, the carbon atoms 314 become sufficiently mobile to diffuse within the carbon-doped metal layer 340, so that the carbon atoms 314 are dissolved in the carbon-doped metal layer 340. The heating process 342 is reduced, causing the temperature of the carbon-doped metal layer 340 to drop. During this process of heating and subsequently cooling the carbon-doped metal layer 340, a first portion of the carbon atoms 314 migrates to a lower surface of the carbon-doped metal layer 340 adjacent to the top surface 304 of the substrate layer 302 and forms a graphene layer 306 over the top surface 304 and under the carbon-doped metal layer 340. A second portion of the carbon atoms 314 migrates to an upper surface of the carbon-doped metal layer 340 and forms a discardable graphitic layer 344 located opposite from the graphene layer 306.

Referring to FIG. 3E, a contact etch mask 352 is formed over the discardable graphitic layer 344, covering areas for subsequently-formed contact layers of the carbon-doped metal layer 340. The contact etch mask 352 may include photoresist formed by a photolithographic process. In the instant example, the discardable graphitic layer 344 may be removed where exposed by the contact etch mask 352 using a plasma process 346. The discardable graphitic layer 344 is much thinner than the contact etch mask 352, allowing removal of the discardable graphitic layer 344 without significantly degrading the contact etch mask 352.

Referring to FIG. 3F, the carbon-doped metal layer 340 of FIG. 3E is removed where exposed by the contact etch mask 352, leaving the remaining carbon-doped metal layer 340 under the contact etch mask 352 to provide contact layers 310 on the graphene layer 306. The process of removing the carbon-doped metal layer 340 may be performed using a wet etch process 354, as disclosed in reference to FIG. 2G. After the contact layers 310 are formed, the contact etch mask 352 is removed.

Referring to FIG. 3G, the graphene layer 306 and the contact layers 310 provide members of a component 308 of the electronic device 300. In the instant example, the component 308 is represented as a resistor 308 in which the graphene layer 306 provides a body of the resistor 308. An upper dielectric layer 316 is formed over the substrate layer 302 and over the component 308. Vertical contacts 330 are formed in through the upper dielectric layer 316 and through the discardable graphitic layer 344 to make electrical connections to the contact layers 310. The contact layers provide low resistance electrical connections between the vertical contacts 330 and the graphene layer 306. The vertical contacts 330 may have a liner 332 and fill metal structure 334 as depicted in FIG. 3G, or may have any of the structures disclosed in reference to FIG. 1.

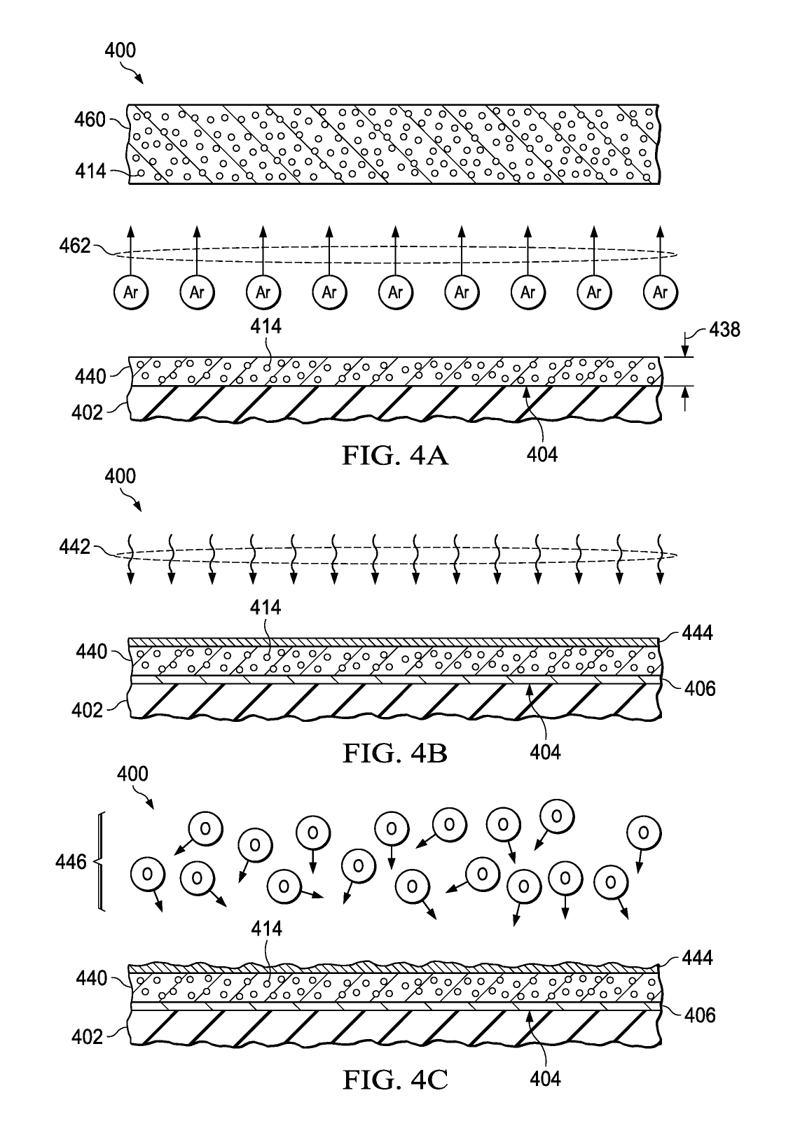

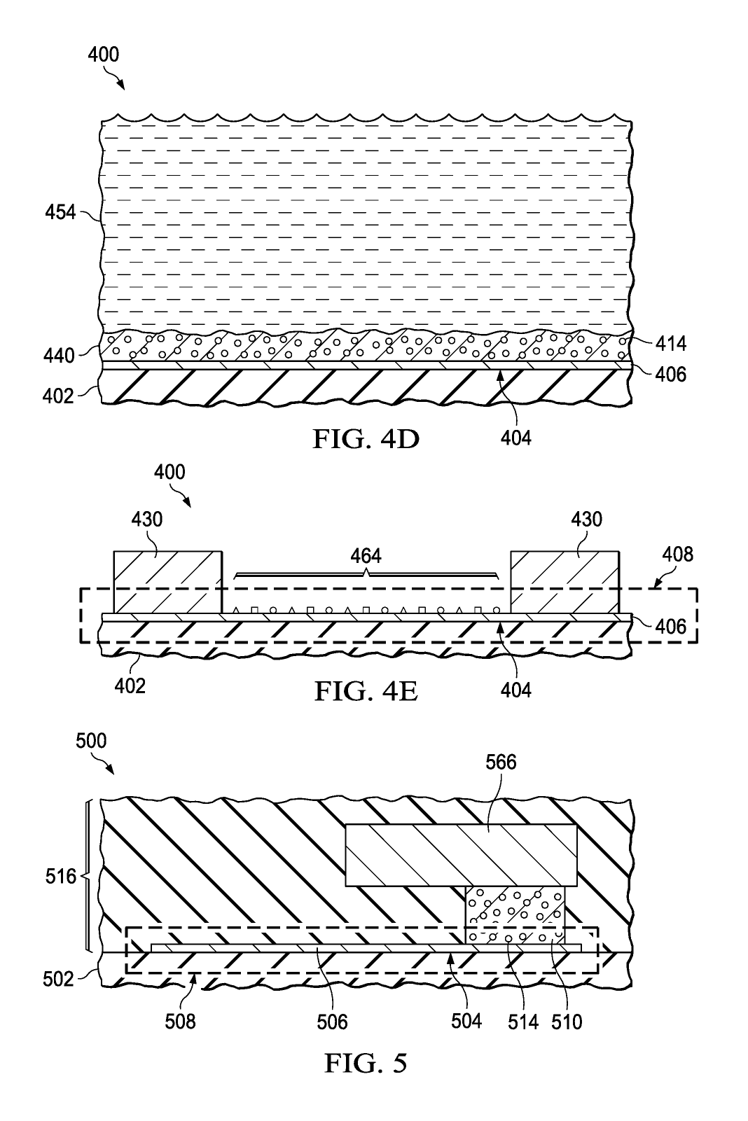

FIGS. 4A through 4E depict another method of forming a carbon-doped metal layer for a process of forming an electronic device having a graphene layer with carbon-doped contact layers. The electronic device 400 has a substrate layer 402 with a top surface 404. A carbon-doped metal layer 440 is formed on the top surface 404 by a physical vapor deposition (PVD) process, using a carbon-doped metal target 460. The carbon-doped metal target 460 includes carbon atoms 414 of a sufficient density to provide a desired density of the carbon atoms 414 in the carbon-doped metal layer 440. The PVD process may use an inert gas ambient, represented in FIG. 4 by argon ions 462 to sputter metal and carbon from the carbon-doped metal target 460, which are subsequently incorporated into the carbon-doped metal layer 440 on the substrate layer 402. Forming the carbon-doped metal layer 440 by the PVD process may reduce fabrication cost and complexity of the electronic device 400.

After forming the carbon-doped metal layer 440 by the PVD process, the graphene layer is formed on the top surface 404 of the substrate layer 402 from the carbon atoms 414 in the carbon-doped metal layer 440. The graphene layer may be formed, for example, as disclosed in reference to FIG. 3D. A thickness 438 of the carbon-doped metal layer 440 is such that there are sufficient carbon atoms 414 in the carbon-doped metal layer 440 to form the graphene layer. The carbon-doped contact layers are formed of the carbon-doped metal layer 440, for example as disclosed in reference to FIG. 2F and FIG. 2G, or in reference to FIG. 3E and FIG. 3F.

FIG. 5 is a cross section of another example electronic device having a graphene layer and a contact layer of carbon-doped metal on the graphene layer. The electronic device 500 has a substrate layer 502 with a top surface 504. The electronic device 500 includes a graphene layer 506 disposed over the top surface 504. The graphene layer 506 provides a conductive member of a component 508 of the electronic device 500. In the instant example, the component 508 is represented as an antenna 508. Other implementations of the component 508 using the graphene layer 506, such as a transistor, resistor, capacitor, or sensor, are within the scope of the instant example. A contact layer 510 of carbon-doped metal is disposed directly on the graphene layer 506. The contact layer 510 does not extend over the entire graphene layer 506. Carbon atoms 514 are depicted schematically in FIG. 5 by circles. A contact resistivity between the contact layer 510 and the graphene layer 506 may be less than 10⁻⁷ ohm cm².

An upper dielectric layer 516 is disposed over the substrate layer 502 and the graphene layer 506. The upper dielectric layer 516 may include a plurality of sub-layers of dielectric material. In the instant example, a lateral interconnect 564 is disposed directly on the contact layer 510. For the purposes of this disclosure, the term “lateral” is understood to refer to a direction parallel to a plane of the instant top surface of the electronic device 500. The lateral interconnect 564 may be, for example, an aluminum interconnect, a damascene copper interconnect, or a plated copper interconnect. An aluminum interconnect may include an aluminum layer with a few percent silicon, titanium, and/or copper, possibly on an adhesion layer including titanium, and possibly with an anti-reflection layer of titanium nitride on the aluminum layer. A damascene copper interconnect may include copper on a barrier layer of tantalum and/or tantalum nitride, disposed in a trench. A plated copper interconnect may include a main layer of plated copper, an adhesion layer at a bottom of the plated copper main layer, and may have a barrier layer disposed on the sides of the plated copper main layer. Other structures and materials for the lateral interconnect 564, such as carbon nanotube bundles, graphene layers, and such, are within the scope of the instant example. Having the lateral interconnect 564 directly on the contact layer 510 may enable an advantageously compact structure for the electronic device 500.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

1. An electronic device, comprising:
a substrate layer having a top surface;
a graphene layer, comprising at least one atomic layer of graphene layer, over the substrate layer;
a contact layer directly on the graphene layer, the contact layer comprising carbon-doped metal, wherein the contact layer is adjacent a portion of the graphene layer for which the carbon-doped metal layer is absent; and
a graphitic layer directly on the contact layer.

2. The electronic device of claim 1, wherein the carbon-doped metal comprises a metal selected from the group consisting of cobalt, nickel, copper, ruthenium, rhodium, palladium, silver, rhenium, iridium, platinum, and gold.

3. The electronic device of claim 1, wherein a concentration of carbon atoms in the carbon-doped metal is approximately equal to a saturation concentration of carbon in the carbon-doped metal between approximately 400° C. and approximately 1100° C.

4. (canceled)

5. The electronic device of claim 1, further comprising a vertical contact on the contact layer.

6. The electronic device of claim 1, further comprising a lateral interconnect on the contact layer.

7. The electronic device of claim 1, wherein the graphene layer provides a channel layer of a field effect transistor, and wherein the contact layer provides a drain terminal of the field effect transistor.

8-20. (canceled)

21. The electronic device of claim 5, wherein the vertical contact includes a liner material in direct contact with the contact layer.

22. The electronic device of claim 1, wherein the contact layer is a first contact layer, and further comprising a second contact layer and a gate dielectric layer directly on the graphene layer and located between the first and second contact layers.

23. The electronic device of claim 22, wherein the gate dielectric layer comprises a high-k dielectric material.

24. The electronic device of claim 22, further comprising a gate structure located on the gate dielectric layer.

25. The electronic device of claim 24, wherein said gate structure comprises polysilicon.

26. The electronic device of claim 1, further comprising a SiN liner directly on the contact layer and the graphene layer portion.

27. The electronic device of claim 1, further comprising a dielectric layer located between the graphene layer and a semiconductor substrate, wherein the graphene layer is in direct contact with the dielectric layer.

28. The electronic device of claim 1, wherein the contact layer has a thickness in a range between about 50 nm and about 500 nm.

29. A field effect transistor, comprising:
a graphene layer over a substrate;
first and second contact layers located directly on the graphene layer, the first and second contact layers comprising a carbon-doped metal;
a graphitic layer directly on each of the first and second contact layers;
a gate located between the first and second contact layers; and
a gate dielectric layer located between the gate and the graphene layer.

30. The transistor of claim 29, wherein the carbon-doped metal comprises a metal selected from the group consisting of cobalt, nickel, copper, ruthenium, rhodium, palladium, silver, rhenium, iridium, platinum, and gold.

31. The transistor of claim 29, wherein the first contact layer provides a source terminal, the second contact layer provides a drain terminal, and the graphene layer provides a channel layer conductively connected to the source and drain terminals.

32. (canceled)

33. An integrated circuit, comprising:
a plurality of transistors configured to cooperate to perform an electrical function, at least one transistor being a field effect transistor comprising:
a graphene layer over a substrate;
first and second contact layers located directly on the graphene layer, the first and second contact layers comprising a carbon-doped metal;
a graphitic layer directly on each of the first and second contact layers;
a gate located between the first and second contact layers; and
a gate dielectric layer located between the gate and the graphene layer.
